(19) United States
(12) Patent Application Publication
(10) Pub. No.: US 2012/0168873 A1
(43) Pub. Date: Jul. 5, 2012

(54) TRANSMISSION GATES WITH ASYMMETRIC FIELD EFFECT TRANSISTORS

(75) Inventors: Brent A. Anderson, Jericho, VT (US); Andres Bryant, Burlington, VT (US); Edward J. Nowak, Essex Junction, VT (US)

(73) Assignee: INTERNATIONAL BUSINESS MACHINES CORPORATION, Armonk, NY (US)

(21) Appl. No.: 12/984,773

(22) Filed: Jan. 5, 2011

(51) Int. Cl. H01L 21/70; G06F 17/50; H01L 21/8238

(52) U.S. Cl. 257/369; 438/217; 716/104; 257/E21.532; 257/E21.632

(57) ABSTRACT

Transmission gates, methods of fabricating transmission gates, and design structures for a transmission gate. The transmission gate includes an n-channel field effect transistor characterized by terminals that are asymmetrically doped and a p-channel field effect transistor characterized by terminals that are asymmetrically doped.

### BACKGROUND

The invention relates generally to semiconductor device fabrication and, in particular, to transmission gates, methods of making transmission gates, and device structures for a transmission gate.

A transmission gate is a fundamental and ubiquitous component in complementary metal-oxide-semiconductor (CMOS) logic. The transmission gate is comprised of a parallel combination of an n-channel metal-oxide semiconductor field-effect transistor (MOSFET) and a p-channel MOSFET. The transmission gate will selectively block or pass a signal level from the input terminal of the transmission gate to the output terminal of the transmission gate. The control gate electrodes of the MOSFETs are biased in a complementary manner so that both field-effect transistors are either in an ON state to pass the signal level or in an OFF state to block the signal level. Transmission gates may be used, for example, in an integrated circuit to feed a latch.

Improved transmission gates and fabrication methods for transmission gates, as well as design structures for transmission gates, are needed.

### BRIEF SUMMARY

In an embodiment of the invention, a device structure for a transmission gate includes an n-channel field effect transistor (nFET) having a first terminal, a second terminal, a channel region between the first terminal and the second terminal, and a gate electrode overlying the channel region. The nFET has a first threshold voltage when the nFET is operated with the first terminal of the nFET as a source. The nFET has a second threshold voltage when the nFET is operated with the first terminal of the nFET as a drain. An absolute value of the second threshold voltage for the nFET is smaller than an absolute value of the first threshold voltage for the nFET. The transmission gate further includes a p-channel field effect transistor (pFET) including a first terminal, a second terminal, a channel region between the first terminal and the second terminal, a gate overlying the channel region. The pFET has a first threshold voltage when the pFET is operated with the first terminal of the pFET as a source. The pFET has a second threshold voltage when the pFET is operated with the first terminal of the pFET as a drain. An absolute value of the second threshold voltage for the pFET is smaller than an absolute value of the first threshold voltage for the pFET. An input terminal is coupled to the first terminal of the nFET and to the first terminal of the pFET. An output terminal is coupled to the second terminal of the nFET and to the second terminal of the pFET.

In an embodiment of the invention, a method of fabricating a transmission gate includes implanting a first halo implant region in a channel region adjacent to a first terminal of an nFET and implanting a second halo implant region in a channel region adjacent to a first terminal of a pFET. The first halo implant region asymmetrically provides a dopant profile in the channel region for the nFET adjacent to the first terminal that differs from a dopant profile in the channel region for the nFET adjacent to the second terminal. The second halo implant region provides a dopant profile in the channel region for the pFET adjacent to the first terminal that differs from a dopant profile in the channel region for the pFET adjacent to the second terminal. The method further includes coupling an input terminal to the first terminal of the nFET and to the first terminal of the pFET, and coupling an output terminal to the second terminal of the nFET and to the second terminal of the pFET.

In another embodiment, a hardware description language (HDL) design structure is encoded on a machine-readable data storage medium. The HDL design structure comprises elements that, when processed in a computer-aided design system, generates a machine-executable representation of a transmission gate. The HDL design structure comprises an n-channel field effect transistor (nFET) including a first terminal, a second terminal, a channel region between the first terminal and the second terminal, and a gate electrode overlying the channel region. The nFET has a first threshold voltage when the nFET is operated with the first terminal of the nFET as a source. The nFET has a second threshold voltage when the nFET is operated with the first terminal of the nFET as a drain. An absolute value of the second threshold voltage for the nFET is smaller than an absolute value of the first threshold voltage for the nFET. The HDL design structure further comprises a p-channel field effect transistor (pFET) including a first terminal, a second terminal, a channel region between the first terminal and the second terminal, a gate overlying the channel region. The pFET has a first threshold voltage when the pFET is operated with the first terminal of the pFET as a source. The pFET has a second threshold voltage when the pFET is operated with the first terminal of the pFET as a drain. An absolute value of the second threshold voltage for the pFET is smaller than an absolute value of the first threshold voltage for the pFET. The HDL design structure further comprises an input terminal coupled to the first terminal of the nFET and to the first terminal of the pFET. The HDL design structure further comprises an output terminal coupled to the second terminal of the nFET and to the second terminal of the pFET.

### BRIEF DESCRIPTION OF THE SEVERAL VIEWS OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIG. 1 is a diagrammatic top view of a transmission gate in accordance with an embodiment of the invention.

FIG. 1A is a diagrammatic cross-sectional view taken generally along line 1A-1A in FIG. 1.

FIG. 1B is a diagrammatic cross-sectional view taken generally along line 1B-1B in FIG. 1.

FIG. 2 is a schematic illustrating the electrical configuration of the transmission gate in FIG. 1.

FIG. 3 is a flow diagram of a design process used in semiconductor design, manufacture, and/or test.

### DETAILED DESCRIPTION

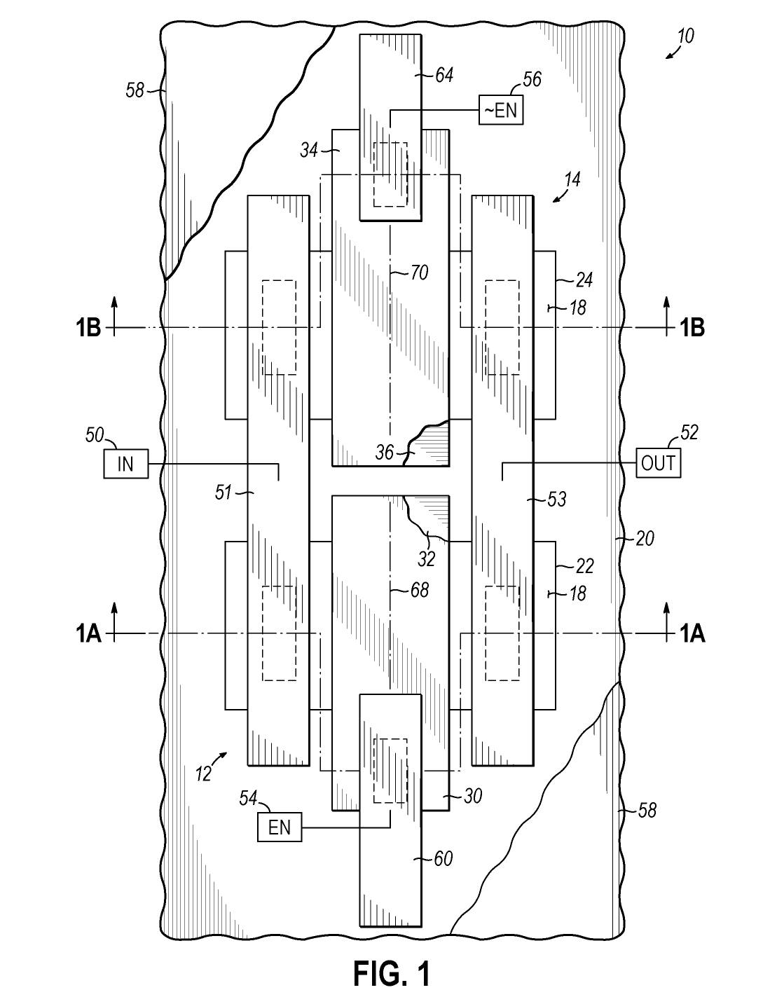

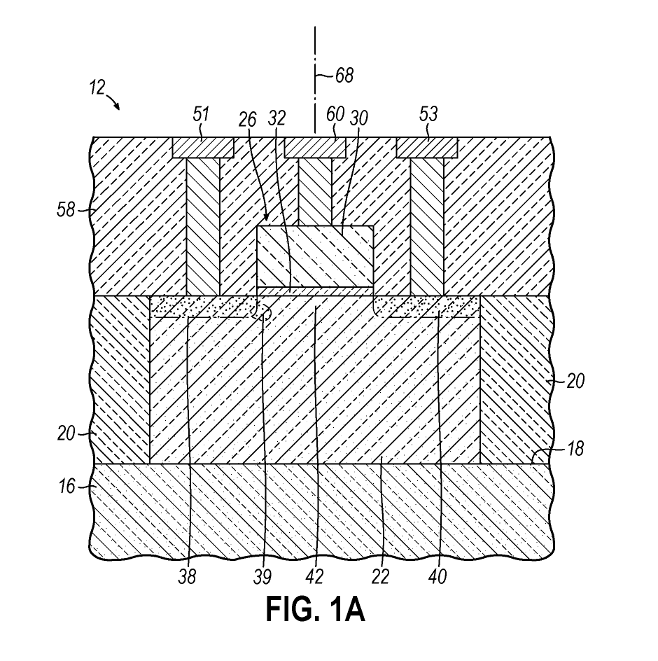

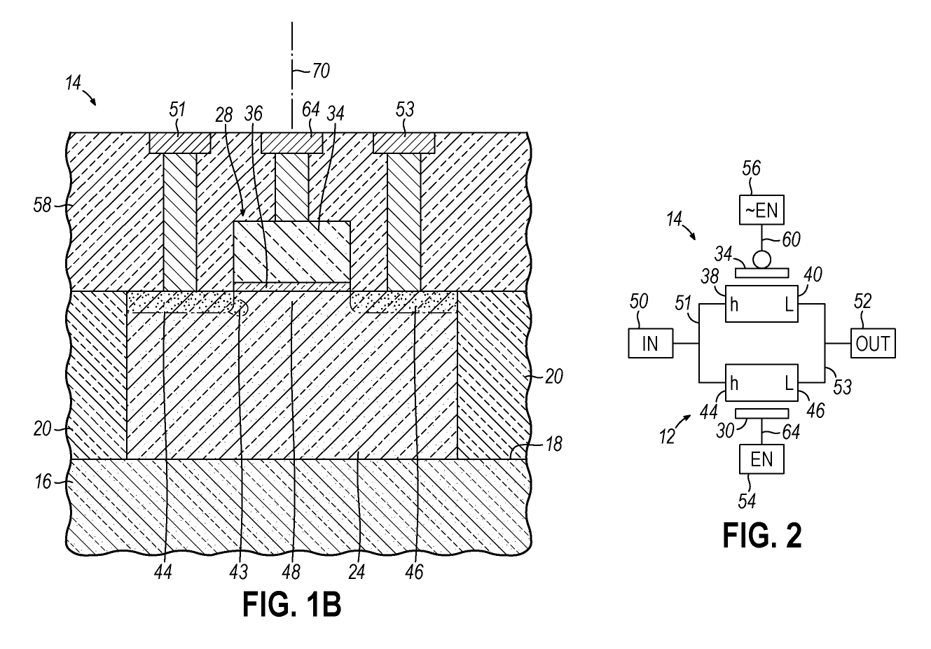

With reference to FIGS. 1, 1A, and 1B and in accordance with an embodiment of the invention, a pass gate or transmission gate 10 includes an n-channel metal-oxide semiconductor field-effect transistor or nFET 12 and a p-channel MOSFET or pFET 14 that are coupled in parallel. The transmission gate 10 is fabricated using a semiconductor layer 16 is comprised of a semiconductor material that a person having ordinary skill in the art would recognize as suitable for forming an integrated circuit. For example, the semiconductor layer 16 may be comprised of a monocrystalline silicon-containing material, such as bulk single crystal silicon or a silicon-on-insulator (SOI) layer. The semiconductor material constituting semiconductor layer 16 may be lightly doped with an impurity to alter its electrical properties. Specifically, the semiconductor layer 16 may be lightly doped with a concentration of an n-type impurity species (e.g., arsenic) to render it initially lightly doped n-type (n⁻) semiconductor material or lightly doped with a concentration of a p-type impurity species (e.g., boron or indium) to render it initially lightly doped p-type (p⁻) semiconductor material. The semiconductor layer 16 may be an epitaxial layer grown on a bulk substrate of higher doping (e.g., p⁺) and the light-doping state of semiconductor layer 14 may result from doping during epitaxial growth. In an extremely thin semiconductor on insulator (ETSOI) technology, the semiconductor layer 16 may have a representative thickness of 20 nm or less.

An isolation structure 20 includes a series of continuous dielectric regions defined by a conventional process in the semiconductor layer 16. In one embodiment, the isolation structure 20 is formed by a shallow-trench isolation (STI) technique that relies on a conventional lithography and dry etching process to define trenches, fills the trenches with portions of a dielectric material, and planarizes the layer to a top surface 18 of semiconductor layer 16 using a chemical mechanical polishing (CMP) process. After the planarization, residual dielectric material disposed inside the trenches defines the dielectric regions of the isolation structure 20. The dielectric material comprising the isolation structure 20 may be an oxide, such as densified tetraethylorthosilicate (TEOS) deposited by thermal chemical vapor deposition (CVD) or a high-density-plasma (HDP) oxide deposited with plasma assistance. The isolation structure 20 delineates and bounds device regions 22, 24 of the semiconductor layer 16, which are electrically isolated from adjacent devices regions (not shown) and each other.

Device region 22 is used to fabricate the nFET 12 and the device region 24 is used to fabricate the nFET 14. Device region 22 may be doped to provide a p-type well or body for the nFET 12 and device region 24 may be doped to provide an n-type well or body for the pFET 14. Process for providing body doping are understood by a person having ordinary skill in the art.

Gate structures 26, 28 are respectively formed for nFET 12 and the pFET 14. Gate structure 26 for the nFET 12 includes a gate electrode 30 and a gate dielectric 32 separating the gate electrode 30 from the top surface 18 of the device region 22. Gate structure 28 for the pFET 12 includes a gate electrode 34 and a gate dielectric 36 separating the gate electrode 34 from the top surface 18 of the device region 24.

The gate structures 26, 28 are formed from a layer stack that includes a thin dielectric layer on the top surface 18 of the semiconductor layer 16 and one or more layers of a conductor on the thin dielectric layer. Candidate dielectric materials for dielectric layer include, but are not limited to, silicon oxynitride (SiOₓN_{y}), silicon nitride (Si₃N₄), silicon dioxide (SiO₂), hafnium-based dielectric materials like hafnium oxide (HfO₂), hafnium silicate (HfSiO), or nitrided hafnium silicate (HfSiON), aluminum oxide (Al₂O₃), lanthanum oxide (La₂O₃), titanium dioxide (TiO₂), tantalum oxide (Ta₂O₅), zirconium oxide (ZrO₂), zirconium silicon oxide (ZrSiO), yttrium oxide (Y₂O₃), strontium oxide (SrO), or strontium titanium oxide (SrTiO), mixtures thereof, or layered stacks of these and other dielectric materials. The dielectric layer deposited by a deposition process like atomic layer deposition (ALD), chemical vapor deposition (CVD), or another conventional deposition technology or, if comprised of SiO₂, may be oxide grown by a wet or dry oxidation process executed as understood by a person having ordinary skill in the art. Candidate materials for the conductor layer include, but are not limited to, a metal, doped polysilicon, a metal nitride, a metal silicide, or a layered stack of these conductive materials, and are characterized by a significantly higher electrical conductivity than the dielectric material. In one embodiment, the conductor layer may be comprised of doped polysilicon deposited by CVD using either silane or disilane as a silicon source. The conductor and dielectric layers are patterned by a conventional lithography and etching process to define the gate structures 26, 28. Optional dielectric spacers (not shown) may be applied to the sidewalls of the gate structures 26, 28 by a conventional spacer formation process.

A terminal 38 and a terminal 40 of the nFET 12 are formed in the p-well in the device region 22. A planar channel region 42 is defined in the device region 22 between the terminals 38, 40 of the nFET 12. To form the terminals, an implantation mask (not shown) is formed on the top surface 18 of semiconductor layer 16. In one embodiment, the ion implantation mask may be formed by applying a layer of a resist material, exposing the resist layer to a pattern of radiation, and developing the exposed resist layer to define a window in the resist layer. The window in the ion implantation mask spatially coincides with the device region 22 and the mask covers the device region 24 to block implantation into the device region 24 for the pFET 14. The device region 22 of semiconductor layer 16 is implanted with energetic ions of an impurity species from Group V of the Periodic Table (e.g., phosphorus, arsenic or antimony) that is effective to act as a dopant in the semiconductor material of the semiconductor layer 16 to impart an n-type conductivity for the terminals 38, 40. The gate structure 26 assists in aligning the implanted ions to form the terminals 38, 40, which may be heavily doped n-type semiconductor material. The terminals 38, 40 may be characterized by the same average dopant concentration and comprise equal doped volumes of semiconductor material.

A halo implant region 39 is formed in the channel region 42 adjacent to the terminal 38 of the nFET 12 using, for example, the same implantation mask used to form the terminals 38, 40 or a different block mask specifically dedicated to the halo implant and tailored to provide a desired dopant profile of a p-type dopant in the device region 22. The halo implant region 39 may be formed using an angled implantation conducted at a low energy and at a non-normal angle of incidence, such as an incident angle ranging from 10° to 45° from normal incidence. The p-type dopant used to form the halo implant region 39 is an impurity species from Group III of the Periodic Table (e.g., boron or indium) effective to act as a dopant to impart a p-type conductivity in the semiconductor material of the device region 22 of semiconductor layer 16. The terminals 38, 40 are n-type, preferably heavily-doped n-type, and the halo implant region 39 is doped p-type. The implantation conditions (e.g., dose and kinetic energy) for the halo implant are selected according to a desired device specification for the nFET 12. In one embodiment, the halo implant may be performed at an energy ranging from 2 keV to 80 keV. In one embodiment, the ion dose for the halo implant may range from 5×10¹² ions/cm² to 9×10¹³ ions/cm².

In contrast to conventional angled implantations used to form CMOS halo implant regions, the substrate bearing the semiconductor layer 16 is not reoriented in the ion implanter but is held in a static angular orientation so that the ions of the halo implant preferentially penetrate into the channel region 42 adjacent to terminal 38 but do not penetrate into the channel region 42 adjacent to terminal 40. Terminal 40 of the nFET 12 is masked by the gate structure 26 and implantation mask against receiving a dose of the p-type dopant during the angled implantation forming the halo implant region 39. The halo implant region 39 has a depth profile of the dopant atomic concentration characterized by a distribution with a peak concentration at a projected range and a range straggle that represents a standard deviation or second moment about the projected range. Because of the off-normal angled incidence of the ions, the halo implant region 39 penetrates laterally a short distance into the channel region 42 beneath the gate structure 26 adjacent to terminal 38.

Following the halo implant, the dopant profile of the nFET 12 is asymmetrical because of the presence of the halo implant region 39 in the channel region 42 adjacent to terminal 38 and the absence of a complementary halo implant region in the channel region 42 adjacent to terminal 40. The asymmetrical dopant profile may be attributed to the dopant concentration and/or the doped volume of semiconductor material in the device region 22. The asymmetry in the doping may be assessed relative to a plane 68 that extends through the center of the nFET 12 with terminal 38 and halo implant region 39 on one side of the plane and terminal 40 on the opposite side of the plane 68. The doping profile on the side of the plane 68 that includes terminal 38 and halo implant region 39 includes a larger doped volume of semiconductor material or a larger dopant concentration than the doping profile on the side of the plane 68 that includes terminal 40.

The nFET 12 has a more-positive threshold voltage when operated with the terminal 38 as a source and the nFET 12 has a less-positive threshold voltage when operated with the terminal 38 as a drain. In other words, an absolute value of the less-positive threshold voltage for the nFET 12 is smaller than an absolute value of the more-positive threshold voltage for the nFET 12. The difference arises from the difference in the doping of the channel region 42 adjacent to terminal 38 in comparison with the doping of the channel region 42 adjacent to terminal 40 that, in the representative embodiment, is produced by the presence of the halo implant region 39.

A terminal 44 and a terminal 46 of the pFET 14 are formed in the N-well in device region 24. A planar channel region 48 is defined in device region 24 between the terminals 44, 46 of the pFET 14. Another implantation mask (not shown) is formed on the top surface 18 of semiconductor layer 16. The window in the ion implantation mask spatially coincides with the device region 24 and the mask covers the device region 22 to block implantation into the device region 22 for the nFET 12. The device region 24 of semiconductor layer 16 is implanted with energetic ions of an impurity species from Group III of the Periodic Table (e.g., boron or indium) effective to act as a dopant to impart a p-type conductivity in the semiconductor material of the semiconductor layer 16. The gate structure 26 assists in aligning the implanted ions to form the terminals 44, 46, which may be heavily doped p-type semiconductor material. The terminals 44, 46 may be characterized by the same average dopant concentration and comprise equal doped volumes of semiconductor material.

A halo implant region 43 is formed in the channel region 48 adjacent to the terminal 44 of the pFET 14 using, for example, the same implantation mask used to form the terminals 44, 46 or a different block mask specifically dedicated to the halo implant and tailored to provide a desired dopant profile of a p-type dopant in the device region 24. The halo implant region 43 may be formed using an angled implantation conducted at a low energy and at a non-normal angle of incidence, such as an incident angle ranging from 10° to 45° from normal incidence. The n-type dopant used to form the halo implant region 43 is an impurity species from Group V of the Periodic Table (e.g., phosphorus, arsenic or antimony) effective to act as a dopant to impart an n-type conductivity in the semiconductor material of the device region 24 of semiconductor layer 16. The terminals 44, 46 are p-type, preferably heavily-doped p-type, and the halo implant region 43 is doped n-type. The implantation conditions (e.g., dose and kinetic energy) for the halo implant are selected according to a desired device specification for the pFET 14. In one embodiment, the halo implant may be performed at an energy ranging from 2 keV to 80 keV. In one embodiment, the ion dose for the halo implant may range from 5×10¹² ions/cm² to 9×10¹³ ions/cm².

In contrast to conventional angled implantations used to form CMOS halo implant regions, the substrate bearing the semiconductor layer 16 is not reoriented in the ion implanter but is held in a static angular orientation so that the ions of the halo implant preferentially penetrate into the channel region 48 adjacent to terminal 44 but do not penetrate into the channel region 48 adjacent to terminal 46. Terminal 46 of the pFET 14 is masked by the gate structure 28 and implantation mask against receiving a dose of the p-type dopant during the angled implantation forming the halo implant region 43. The halo implant region 43 has a depth profile of the dopant atomic concentration characterized by a distribution with a peak concentration at a projected range and a range straggle that represents a standard deviation or second moment about the projected range. Because of the off-normal angled incidence of the ions, the halo implant region 43 penetrates laterally a short distance into the channel region 48 beneath the gate structure 28 adjacent to terminal 44.

Following the halo implant, the dopant profile of the pFET 14 is asymmetrical is asymmetrical because of the presence of the halo implant region 43 adjacent to terminal 44 and the absence of a complementary halo implant region adjacent to terminal 46. The asymmetrical dopant profile may be attributed to the dopant concentration and/or the doped volume of semiconductor material in the device region 24. The asymmetry in the doping may be assessed relative to a plane 70 that extends through the center of the pFET 14 with terminal 44 and halo implant region 43 on one side of the plane and terminal 46 on the opposite side of the plane 70. The doping profile on the side of the plane 70 that includes terminal 44 and halo implant region 43 includes a larger doped volume of semiconductor material or a larger dopant concentration than the doping profile on the side of the plane 70 that includes terminal 46.

The pFET 14 has a more-negative threshold voltage when operated with the terminal 44 as a source and a less-negative threshold voltage when operated with the terminal 44 as a drain. In other words, an absolute value of the less-positive threshold voltage for the pFET 14 is smaller than an absolute value of the less-negative threshold voltage for the pFET 14. The difference arises from the difference in the doping of the channel region 48 adjacent to terminal 44 in comparison with the doping of the channel region 48 adjacent to terminal 46 that, in the representative embodiment, is produced by the presence of the halo implant region 43.

A thermal treatment, such as a rapid thermal anneal, may be required to electrically activate the impurity species introduced into the device regions 22, 24 of the semiconductor layer 16 by the various implantations and to alleviate implantation damage.

The electrical connections for the transmission gate 10 may be supplied at the local interconnect (CA) level such that the nFET 12 and the nFET 14 are electrically coupled to other parts of the integrated circuit. The CA level includes a dielectric layer and contact plugs that penetrate through the dielectric layer to land on the terminal 38, terminal 40, terminal 44, terminal 46, gate structure 26, and gate structure 28. Silicide may be formed to provide ohmic contact surfaces and lessen sheet resistance.

Standard back-end-of-line (BEOL) processing follows the formation of the transmission gate 10 to form a BEOL interconnect structure. Each interconnect level in the BEOL interconnect structure may be fabricated by damascene processes, such as a dual damascene process in which a dielectric layer is deposited, vias and trenches are etched in the dielectric layer, and the vias and trenches are filled with a conductor using a single blanket deposition followed by planarization. The damascene process is replicated to stack multiple interconnect levels to form a multi-level, high density interconnection framework. Damascene processes and the materials used in damascene processes are understood by a person having ordinary skill in the art.

With reference to FIGS. 1, 1A, 1B, and 2, the transmission gate 10 is electrically coupled between an input terminal (IN) 50 and an output terminal (OUT) 52. The input terminal (IN) 50 is coupled to terminal 38 of the nFET 12 and is also coupled to the terminal 44 of the pFET 14 at the local interconnect (CA) level by metallization 51 in a dielectric layer 58. The output terminal (OUT) 52 is coupled to the terminal 40 of the nFET 12 and is also coupled to the terminal 46 of the pFET 14 at the local interconnect (CA) level by metallization 53 in dielectric layer 58.

The gate electrode 30 of the nFET 12 is coupled at the local interconnect (CA) level by metallization 60 in dielectric layer 58 with a control signal line 54. The gate electrode 34 of the pFET 14 is coupled at the local interconnect (CA) level by metallization 64 in dielectric layer 58 with a control signal line 56. The gate electrode 30 of the nFET 12 is separately addressable from the gate electrode 34 of the pFET 14.

To operate the transmission gate 10, control signals are supplied to the gate electrode 30 of the nFET 12 and control signals are also independently supplied to the gate electrode 34 of the pFET 14. The control signal at one of the gate electrodes 30, 34 is complementary to the control signal at the other of the gate electrodes 30, 34. When signal transmission or conduction is desired from the input terminal (IN) 50 to the output terminal (OUT) 52, the gate electrode 30 of the nFET 12 may be coupled to a positive voltage (e.g., V_{dd}) and the gate electrode 34 of the pFET 14 may be coupled to a ground voltage (e.g., Vₛₛ). When signal transmission or conduction is to be blocked from the input terminal (IN) 50 to the output terminal (OUT) 52, the gate electrode of the nFET 12 may be coupled to a ground voltage and the gate electrode of the pFET 14 may be coupled to a positive voltage.

In one embodiment, the transmission gate 10 may be used in combination with a latch. The latch may comprise a six-device SRAM cell with two pull-down nFETs and two pull-up pFETs, in addition to the two I/O nFETs. To write data to the latch, a high signal is placed on EN (enable) to the gate electrode 30 of the nFET 12 and a low signal is placed on ˜EN (complementary enable) to the gate electrode 34 of the pFET 14 so that the transmission gate 10 is ON or enabled. In this state, the input terminal (IN) 50 and an output terminal (OUT) 52 are coupled with each other to permit a data writing operation. To isolate the latch, a low signal is placed on EN to the gate electrode of the nFET 12 and a high signal is placed on ˜EN to the gate electrode of the pFET 14 so that the transmission gate 10 is OFF or disabled. Because the input terminal (IN) 50 is decoupled from the output terminal (OUT) 52, data cannot be transferred through the transmission gate 10 to the latch.

The embodiments of the invention are directed to a transmission gate that includes a pFET and an nFET each characterized by source/drain regions in the form of asymmetrically doped terminals. Because the positive-trending transition into the transmission gate is dominated by the conductance of the pFET, the asymmetric pFET has a body leakage maximized on its output node so that the threshold voltage Vt is at its lowest when the pFET is actively pulling up the output node. Similarly, the nFET is designed with body leakage maximized on its output node so that the threshold voltage Vt is at its lowest when a downward input transition enters the transmission gate. The disturb condition of the transmission gate may have a high immunity to fall disturb.

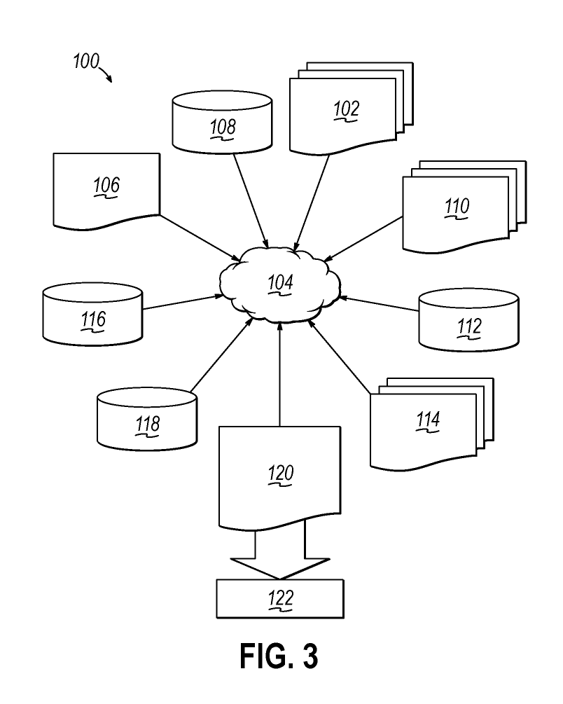

FIG. 3 shows a block diagram of an exemplary design flow 100 used for example, in semiconductor IC logic design, simulation, test, layout, and manufacture. Design flow 100 includes processes, machines and/or mechanisms for processing design structures or devices to generate logically or otherwise functionally equivalent representations of the design structures and/or devices described above and shown in FIGS. 1, 1A, 1B, 2. The design structures processed and/or generated by design flow 100 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g., e-beam writers), computers or equipment for simulating design structures, any apparatus used in the manufacturing or test process, or any machines for programming functionally equivalent representations of the design structures into any medium (e.g., a machine for programming a programmable gate array).

Design flow 100 may vary depending on the type of representation being designed. For example, a design flow 100 for building an application specific IC (ASIC) may differ from a design flow 100 for designing a standard component or from a design flow 100 for instantiating the design into a programmable array, for example a programmable gate array (PGA) or a field programmable gate array (FPGA) offered by Altera® Inc. or Xilinx® Inc.

FIG. 3 illustrates multiple such design structures including an input design structure 102 that is preferably processed by a design process 104. Design structure 102 may be a logical simulation design structure generated and processed by design process 104 to produce a logically equivalent functional representation of a hardware device. Design structure 102 may also or alternatively comprise data and/or program instructions that when processed by design process 104, generate a functional representation of the physical structure of a hardware device. Whether representing functional and/or structural design features, design structure 102 may be generated using electronic computer-aided design (ECAD) such as implemented by a core developer/designer. When encoded on a machine-readable data transmission, gate array, or storage medium, design structure 102 may be accessed and processed by one or more hardware and/or software modules within design process 104 to simulate or otherwise functionally represent an electronic component, circuit, electronic or logic module, apparatus, device, or system such as those shown in FIGS. 1, 1A, 1B, 2. As such, design structure 102 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 104 preferably employs and incorporates hardware and/or software modules for synthesizing, translating, or otherwise processing a design/simulation functional equivalent of the components, circuits, devices, or logic structures shown in FIGS. 1, 1A, 1B, 2 to generate a Netlist 106 which may contain design structures such as design structure 102. Netlist 106 may comprise, for example, compiled or otherwise processed data structures representing a list of wires, discrete components, logic gates, control circuits, I/O devices, models, etc. that describes the connections to other elements and circuits in an integrated circuit design. Netlist 106 may be synthesized using an iterative process in which netlist 106 is resynthesized one or more times depending on design specifications and parameters for the device. As with other design structure types described herein, netlist 106 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 104 may include hardware and software modules for processing a variety of input data structure types including Netlist 106. Such data structure types may reside, for example, within library elements 108 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 110, characterization data 112, verification data 114, design rules 116, and test data files 118 which may include input test patterns, output test results, and other testing information. Design process 104 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 104 without deviating from the scope and spirit of the invention. Design process 104 may also include modules for performing standard circuit design processes such as timing analysis, verification, design rule checking, place and route operations, etc.

Design process 104 employs and incorporates logic and physical design tools such as HDL compilers and simulation model build tools to process design structure 102 together with some or all of the depicted supporting data structures along with any additional mechanical design or data (if applicable), to generate a second design structure 120. Design structure 120 resides on a storage medium or programmable gate array in a data format used for the exchange of data of mechanical devices and structures (e.g. information stored in an IGES, DXF, Parasolid XT, JT, DRG, or any other suitable format for storing or rendering such mechanical design structures). Similar to design structure 102, design structure 120 preferably comprises one or more files, data structures, or other computer-encoded data or instructions that reside on transmission or data storage media and that when processed by an ECAD system generate a logically or otherwise functionally equivalent form of one or more of the embodiments of the invention shown in FIGS. 1, 1A, 1B, 2. In one embodiment, design structure 120 may comprise a compiled, executable HDL simulation model that functionally simulates the devices shown in FIGS. 1, 1A, 1B, 2.

Design structure 120 may also employ a data format used for the exchange of layout data of integrated circuits and/or symbolic data format (e.g. information stored in a GDSII (GDS2), GL1, OASIS, map files, or any other suitable format for storing such design data structures). Design structure 120 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 1, 1A, 1B, 2. Design structure 120 may then proceed to a stage 122 where, for example, design structure 120: proceeds to tape-out, is released to manufacturing, is released to a mask house, is sent to another design house, is sent back to the customer, etc.

It will be understood that when an element is described as being “connected” or “coupled” to or with another element, it can be directly connected or coupled to the other element or, instead, one or more intervening elements may be present. In contrast, when an element is described as being “directly connected” or “directly coupled” to another element, there are no intervening elements present. When an element is described as being “indirectly connected” or “indirectly coupled” to another element, there is at least one intervening element present.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A device structure for a transmission gate, comprising
an n-channel field effect transistor (nFET) including a first terminal, a second terminal, a channel region between the first terminal and the second terminal, and a gate electrode overlying the channel region, the nFET having a first threshold voltage when the nFET is operated with the first terminal of the nFET as a source, the nFET having a second threshold voltage when the nFET is operated with the first terminal of the nFET as a drain, and an absolute value of the second threshold voltage for the nFET is smaller than an absolute value of the first threshold voltage for the nFET;
a p-channel field effect transistor (pFET) including a first terminal, a second terminal, a channel region between the first terminal and the second terminal, a gate overlying the channel region, the pFET having a first threshold voltage when the pFET is operated with the first terminal of the pFET as a source, the pFET having a second threshold voltage when the pFET is operated with the first terminal of the pFET as a drain, and an absolute value of the second threshold voltage for the pFET is smaller than an absolute value of the first threshold voltage for the pFET;
an input terminal coupled to the first terminal of the nFET and to the first terminal of the pFET; and
an output terminal coupled to the second terminal of the nFET and to the second terminal of the pFET.

2. The device structure of claim 1 further comprising:
a first signal connection coupled to the gate of the nFET for supplying a first control signal to the gate of the nFET; and
a second signal connection coupled to the gate of the pFET for supplying a second control signal to the gate of the nFET that is complementary to the first control signal.

3. The device structure of claim 2 wherein the first control signal is a selectively-applied positive voltage, the second control signal is a selectively-applied ground voltage, the gate of the nFET is coupled to the positive voltage and the gate of the pFET is coupled to the ground voltage when conduction is desired from the input terminal to the output terminal, and the gate of the nFET is coupled to the ground voltage and the gate of the pFET is coupled to the positive voltage when the conduction is blocked from the input terminal to the output terminal.

4. The device structure of claim 3 further comprising:
a first halo implant region in the channel region of the nFET adjacent to the first terminal of the nFET, the first halo implant region providing a dopant profile in the channel region for the nFET adjacent to the first terminal that differs from a dopant profile in the channel region for the nFET adjacent to the second terminal of the nFET.

5. The device structure of claim 3 further comprising:
a second halo implant region in the channel region of the pFET adjacent to the first terminal of the pFET, the second halo implant region providing a dopant profile in the channel region for the pFET adjacent to the first terminal that differs from a dopant profile in the channel region for the pFET adjacent to the second terminal, and the second halo implant region having an opposite conductivity type to the first terminal of the pFET.

6. The device structure of claim 1 further comprising:
a first halo implant region in the channel region of the nFET adjacent to the first terminal of the nFET, the first halo implant region providing a dopant profile in the channel region for the nFET adjacent to the first terminal that differs from a dopant profile in the channel region for the nFET adjacent to the second terminal, and the first halo implant region having an opposite conductivity type to the first terminal of the nFET.

7. The device structure of claim 6 further comprising:
a second halo implant region in the channel region of the pFET adjacent to the first terminal of the pFET, the second halo implant region providing a dopant profile in the channel region for the nFET adjacent to the first terminal that differs from a dopant profile in the channel region for the nFET adjacent to the second terminal and the second halo implant region having an opposite conductivity type to the first terminal of the pFET.

8. The device structure of claim 6 wherein the channel region of the nFET adjacent to the second terminal of the nFET lacks a halo implant region.

9. The device structure of claim 1 further comprising:
a halo implant region in the channel region of the pFET adjacent to the first terminal of the pFET, the halo implant region providing a dopant profile in the channel region for the pFET adjacent to the first terminal that differs from a dopant profile in the channel region for the pFET adjacent to the second terminal of the pFET.

10. The device structure of claim 9 wherein the channel region of the pFET adjacent to the second terminal of the pFET lacks a halo implant region.

11. A method of fabricating a transmission gate, the method comprising:
forming a first halo implant region in a channel region adjacent to a first terminal of an nFET, the first halo implant region providing a dopant profile in the channel region for the nFET adjacent to the first terminal that differs from a dopant profile in the channel region for the nFET adjacent to the second terminal;
forming a second halo implant region in a channel region adjacent to a first terminal of a pFET, the second halo implant providing a dopant profile in the channel region for the pFET adjacent to the first terminal that differs from a dopant profile in the channel region for the pFET adjacent to the second terminal;
coupling an input terminal to the first terminal of the nFET and to the first terminal of the pFET; and
coupling an output terminal to the second terminal of the nFET and to the second terminal of the pFET.

12. The method of claim 11 wherein the first halo implant region is implanted into the channel region of the nFET using an angled implantation of an n-type dopant, and the channel region of the pFET adjacent to the second terminal of the pFET lacks a halo implant region.

13. The method of claim 12 wherein the second halo implant region is implanted into the channel region of the pFET using an angled implantation of a p-type dopant.

14. The method of claim 11 wherein the second halo implant region is implanted into the channel region of the pFET using an angled implantation of a p-type dopant.

15. The method of claim 11 further comprising:
coupling a first signal connection to the gate of the nFET for supplying a first control signal to the gate of the nFET; and
coupling a second signal connection to the gate of the pFET for supplying a second control signal to the gate of the nFET that is complementary to the first control signal.

16. The device structure of claim 1 wherein the first and second terminals of the nFET are n-type semiconductor material formed in a first device region, the first and second terminals of the pFET are p-type semiconductor material formed in a second device region, the first device region contains the channel region of the nFET, the second device region contains the channel region of the pFET, the first halo implant region is p-type, and the second halo region is n-type.

17. A hardware description language (HDL) design structure encoded on a machine-readable data storage medium, the HDL design structure comprising elements that when processed in a computer-aided design system generates a machine-executable representation of a transmission gate, the HDL design structure comprising:
an n-channel field effect transistor (nFET) including a first terminal, a second terminal, a channel region between the first terminal and the second terminal, and a gate electrode overlying the channel region, the nFET having a first threshold voltage when the nFET is operated with the first terminal of the nFET as a source, the nFET having a second threshold voltage when the nFET is operated with the first terminal of the nFET as a drain, and an absolute value of the second threshold voltage for the nFET is smaller than an absolute value of the first threshold voltage for the nFET;
a p-channel field effect transistor (pFET) including a first terminal, a second terminal, a channel region between the first terminal and the second terminal, a gate overlying the channel region, the pFET having a first threshold voltage when the pFET is operated with the first terminal of the pFET as a source, the pFET having a second threshold voltage when the pFET is operated with the first terminal of the pFET as a drain, and an absolute value of the second threshold voltage for the pFET is smaller than an absolute value of the first threshold voltage for the pFET;
an input terminal coupled to the first terminal of the nFET and to the first terminal of the pFET; and
an output terminal coupled to the second terminal of the nFET and to the second terminal of the pFET

18. The HDL design structure of claim 17 wherein the design structure comprises a netlist.

19. The HDL design structure of claim 17 wherein the design structure resides on storage medium as a data format used for the exchange of layout data of integrated circuits.

20. The HDL design structure of claim 17 wherein the design structure resides in a programmable gate array.
